(19) United States
(12) Patent Application Publication
(10) Pub. No.: US 2008/0042279 A1
(43) Pub. Date: Feb. 21, 2008

(54) MOUNTING STRUCTURE OF SEMICONDUCTOR DEVICE HAVING FLUX AND UNDER FILL RESIN LAYER AND METHOD OF MOUNTING SEMICONDUCTOR DEVICE

(75) Inventors: Hyo-Jae BANG, Chungcheongnam-do (KR); Wha-Su SIN, Chungcheongnam-do (KR); Sung-Yeol LEE, Chungcheongnam-do (KR); Yung-Hyun KIM, Gyeonggi-do (KR); Seong-Chan HAN, Chungcheongnam-do (KR); Jung-Hyeon KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/842,858

(22) Filed: Aug. 21, 2007

(30) Foreign Application Priority Data
Aug. 21, 2006 (KR) 2006-0078917

(51) Int. Cl. H01L 23/488; H01L 21/60; H01L 21/66

(52) U.S. Cl. 257/738; 438/127; 438/14; 257/E23.023; 257/E21.506; 257/E21.53

(57) ABSTRACT

A mounting structure of a semiconductor device and a method of mounting the semiconductor device are provided. The mounting structure includes a circuit substrate having a terminal pad. A device substrate is located over the circuit substrate having a ball pad facing the terminal pad of the circuit substrate. A conductive ball is formed between the circuit substrate and the device substrate in order to connect the terminal pad of the circuit substrate to the ball pad of the device substrate. A first soldering flux including an epoxy-based resin connects the conductive ball to the ball pad of the device substrate. An underfill layer is formed between the circuit substrate and the device substrate in order to bury the conductive ball and the first soldering flux. Using the epoxy-based resin, the first soldering flux can substantially prevent crack from being generated in a solder joint between the conductive ball and the ball pad even when the device substrate is thermally deformed due to temperature variations.

### CROSS-REFERENCE TO RELATED PATENT APPLICATION

This application claims the benefit of foreign priority to Korean Patent Application No. 10-2006-0078917, filed on Aug. 21, 2006, the disclosure of which is incorporated herein in its entirety by reference.

### BACKGROUND 1. Field of Invention

Embodiments of the present invention relate generally to semiconductor devices and methods of mounting semiconductor devices. More particularly, embodiments of the present invention relate to a mounting structure of a semiconductor device having flux and an underfill resin layer and a method of mounting such a semiconductor device.

2. Description of Related Art

In line with the accelerating miniaturization of semiconductor products, lighter, thinner, simpler and smaller semiconductor packages are generally in high demand in terms of attaining a higher integration of semiconductor chips. To meet these high demands, Ball Grid Array (BGA) packages that use conductive balls (e.g., solder balls) as mounting members and flip chip packages, which mount semiconductor chips on a circuit board using conductive balls, have been developed.

However, BGA packages and flip chip packages are likely to crack at a solder joint of the conductive balls. In flip chip packages, for example, a thermal stress can be generated within the conductive balls, located between a semiconductor chip and a circuit board, due to a difference in coefficients of thermal expansion (CTE) between the semiconductor chip and the circuit board. Thus, cracks occur in the solder joint of the conductive balls, induced by thermal stress, can degrade the reliability of the semiconductor packages.

### SUMMARY

Embodiments of the present invention exemplarily described herein can be characterized as providing a semiconductor device mounting structure that includes a flux and an underfill resin layer and a method of mounting semiconductor devices.

One embodiment exemplarily described herein can be generally characterized as a semiconductor device that includes a first substrate having a first pad and a second substrate located over the first substrate and having a second pad facing the first pad. A conductive ball connects the first pad to the second pad and a first soldering flux may be located on a portion of the conductive ball adjacent to the second pad. The first soldering flux may include an epoxy-based resin. An underfill layer may be formed between the first substrate and the second substrate to substantially surround the conductive ball and the first soldering flux.

Another embodiment exemplarily described herein can be generally characterized as a semiconductor device that includes a circuit substrate having a terminal pad and a device substrate located on an upper surface of the circuit substrate and having a ball pad facing the terminal pad. A conductive ball connects the terminal pad to the ball pad and a first soldering flux may be located on a portion of the conductive ball adjacent to the ball pad. An underfill layer may be formed between the circuit substrate and the device substrate to substantially surround the conductive ball and the first soldering flux. A modulus of elasticity of the underfill layer may be less than a modulus of elasticity of the first soldering flux.

Yet another embodiment exemplarily described herein can be generally characterized as a method of forming a semiconductor device that includes providing a first substrate having a first pad; forming a conductive ball on the first pad using a first soldering flux comprising an epoxy-based resin; disposing the first substrate on a second substrate having a second pad; connecting the conductive ball to the second pad; and forming an underfill layer between the second substrate and the first substrate to substantially surround the conductive ball and the first soldering flux.

Still another embodiment exemplarily described herein can be generally characterized as a method of forming a semiconductor device that includes providing a device substrate having a ball pad; forming a conductive ball on the ball pad using a first soldering flux; disposing the device substrate on a circuit substrate having a terminal pad; connecting the conductive ball to the terminal pad; and forming an underfill layer between the circuit substrate and the device substrate to substantially surround the conductive ball and the first soldering flux, wherein a modulus of elasticity of the underfill layer is less than a modulus of elasticity of the first soldering flux.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1D are sectional views illustrating an exemplary method of mounting a semiconductor device according to one embodiment; and

FIG. 2 is sectional view illustrating an exemplary method of mounting a semiconductor device according to another embodiment.

### DETAILED DESCRIPTION

Exemplary embodiments of the present invention will now be described more fully with reference to the accompanying drawings. These embodiments may, however, be realized in many different forms and should not be construed as being limited to the embodiments set forth herein; rather, these embodiments are provided so that this disclosure will be thorough and complete, and will fully convey the concept of the invention to one skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus descriptions thereof will not be repeated.

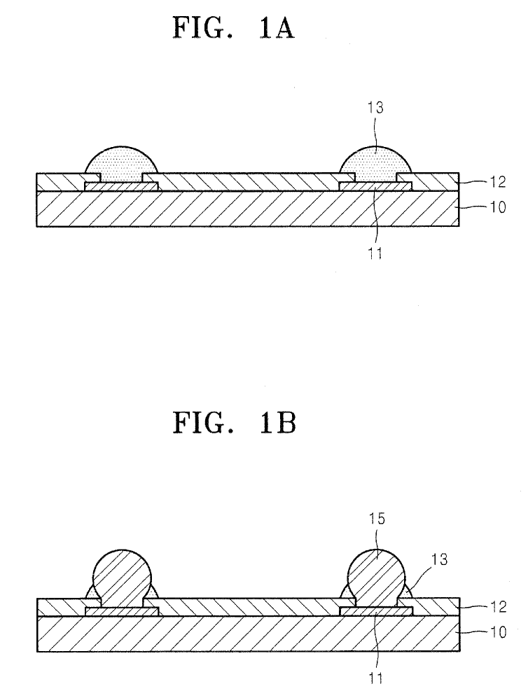

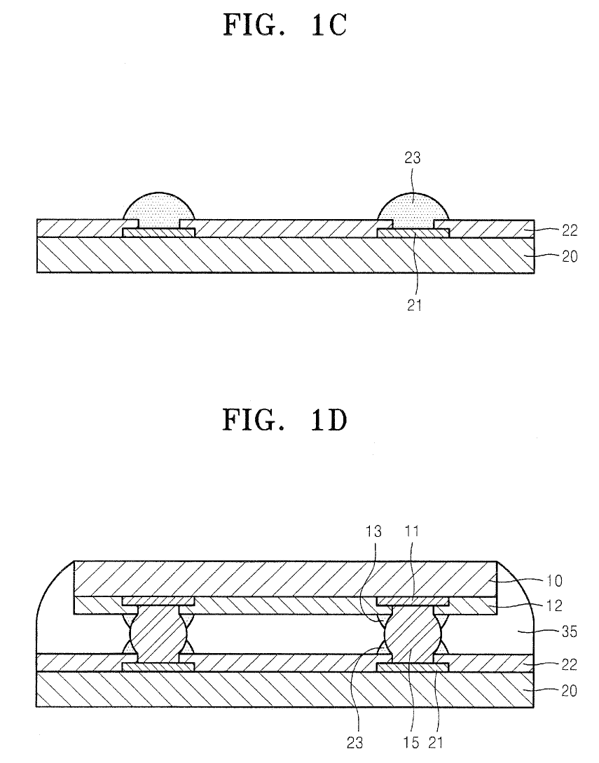

FIGS. 1A through 1D are sectional views illustrating an exemplary method of mounting a semiconductor device according to one embodiment.

Referring to FIG. 1A, a device substrate 10 includes a ball pad 11. The device substrate 10 may be an electrical component (e.g., a semiconductor chip, a circuit board mounted with a semiconductor chip, or the like). The ball pad 11 may comprise a conductive material such as metal (e.g., gold, silver, copper, nickel, aluminum, tin, lead, platinum, bismuth, indium, or the like or combinations thereof). A first solder resist layer 12 having an opening that exposes the ball pad 11 may be formed on the ball pad 11 and the substrate 10.

A first soldering flux 13 may be formed on the ball pad 11 by dotting the first soldering flux 13 on the ball pad 11. The first soldering flux 13 removes an oxide film on a surface of a metal exposed to a conductive material such as solder, prevents re-oxidation of the metal as the metal is exposed to melted conductive material (e.g., melted solder) and decreases surface tension of the melted conductive material, thereby improving spreading and wettability of a subsequently formed conductive ball on the ball pad 11. Flux is conventionally provided as a resin-based flux or a rosin-based flux. However, the first soldering flux 13 used in the present embodiment is an epoxy-based flux that has a relatively high modulus of elasticity compared to the modulus of elasticity of rosin-based fluxes. The modulus of elasticity at room temperature of the epoxy-based flux may range from about 6 GPa to about 10 Gpa. In some embodiments, the modulus of elasticity at room temperature of the epoxy-based flux may be about 7 GPa or more. The epoxy-based flux may further include a filler to improve the modulus of elasticity of the first soldering flux 13. In some embodiments, the filler of the epoxy-based flux may comprise silica, silicon carbide, alumina, or the like or combinations thereof.

Referring to FIG. 1B, a conductive ball 15 may be connected to the ball pad 11 on which the first soldering flux 13 is dotted. In one embodiment, the conductive ball 15 may be a solder ball. In some embodiments, the conductive ball 15 may be adhered onto the ball pad 11 with the dotted first soldering flux 13 on the ball pad 11 and subsequently subjected to a thermal treatment to fix the conductive ball 15 to the ball pad 11. Consequently, the first soldering flux 13 adjacent to the device substrate 10 surrounds a portion of the conductive ball 15. In the illustrated embodiment, the first soldering flux 13 is not formed on substantially the entire surface of the conductive ball 15. Rather, the first soldering flux 13 is restrictively formed on a portion of the conductive ball 15 that is immediately adjacent to the device substrate 10. In some embodiments, the first soldering flux 13 is restrictively formed on a portion of the ball pad 11 that is immediately adjacent to the device substrate 10. In some embodiments, the first soldering flux 13 may connect the conductive ball 15 to the ball pad 11. For example, the first soldering flux 13 may directly contact both the conductive ball 15 and the first solder resist layer 12 and, in so doing, adhere the conductive ball 15 to the first solder resist layer 12. When the conductive ball 15 is adhered to the first solder resist layer 12, the conductive ball 15 is thus connected (e.g., indirectly) to the ball pad 11.

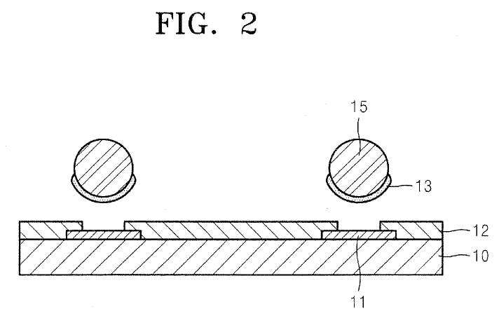

Referring to FIG. 2, which illustrates another embodiment, the first soldering flux 13 is dotted on the conductive ball 15 by dipping. Then, the conductive ball 15 having the first soldering flux 13 dotted thereon may be connected to the ball pad 11 as illustrated in FIG. 1B. In this case, the first soldering flux 13 may also be restrictively formed on only a portion of the conductive ball 15 that is adjacent to the device substrate 10. In some embodiments, the first soldering flux 13 may connect the conductive ball 15 to the ball pad 11. For example, the first soldering flux 13 may directly contact both the conductive ball 15 and the first solder resist layer 12 and, in so doing, adhere the conductive ball 15 to the first solder resist layer 12. When the conductive ball 15 is adhered to the first solder resist layer 12, the conductive ball 15 is thus connected to the ball pad 11.

Due to the relatively high modulus of elasticity of the first soldering flux 13, the conductive ball 15 can be reliably fixed to the device substrate 10 even when the device substrate 10 is thermally deformed. Therefore, cracks in a solder joint between the conductive ball 15 and the device substrate 10, i.e., the ball pad 11, can be substantially prevented. Moreover, a glass transition temperature of the first soldering flux 13 may be higher than a maximum temperature of a thermal shock test performed to test the resultant mounting structure or semiconductor device. For example, when a thermal shock test is performed in a range of 0-125° C., the glass transition temperature of the first soldering flux 13 may be set to be higher than 125° C. Thus, the first soldering flux 13 has a higher modulus of elasticity during the thermal shock test so that cracks occurring in the solder joint between the conductive ball 15 and the ball pad 11 can be prevented.

Referring to FIG. 1C, a circuit substrate 20 includes a terminal pad 21. A second solder resist layer 22 having an opening that exposes the terminal pad 21 may be formed on the terminal pad 21 and the circuit substrate 20. The circuit substrate 20 may be a circuit board formed with an electrical circuit. In some embodiments, the circuit substrate 20 may be a printed circuit board (PCB) or a flexible printed circuit (FPC) film. The terminal pad 21 may be a terminal for inputting an electrical signal to the electrical circuit located on the circuit substrate 20 or outputting an electrical signal from the electrical circuit on the circuit substrate 20. The terminal pad 21 may comprise a conductive material such as metal (e.g., gold, silver, copper, nickel, aluminum, tin, lead, platinum, bismuth, indium, or the like or combinations thereof).

Thereafter, a second soldering flux 23 is dotted and formed on the terminal pad 21. The second soldering flux 23 may be an epoxy-based flux whose modulus of elasticity is relatively high and similar to (or substantially the same as) that of the first soldering flux 13. Furthermore, the second soldering flux 23 may include a filler as described above with respect to the first soldering flux 13.

Referring to FIG. 1D, the device substrate 10 having the conductive ball 15 is disposed on the circuit substrate 20 by facing the conductive ball 15 with the terminal pad 21. Then, the conductive ball 15 may be connected to the terminal pad 21. By doing so, the second soldering flux 23 may be restrictively formed on a portion of the conductive ball 15 that is adjacent to the circuit substrate 20 in a similar manner as discussed above with respect to the first soldering flux 13.

Because of the relatively high modulus of elasticity of the second soldering flux 23, the conductive ball 15 can be reliably fixed onto the circuit substrate 20 even when the circuit substrate 20 is thermally deformed due to temperature variations. Thus, cracks in the solder joint between the conductive ball 15 and the circuit substrate 20, i.e. the terminal pad 21, can be prevented.

Subsequently, an underfill resin layer 35 may be formed to bury the conductive ball 15 and the first and second soldering fluxes 13 and 23 between the circuit substrate 20 and the device substrate 10. As such, a mounting structure of the semiconductor device is completed. In some embodiments, the underfill resin layer 35 firmly bonds the device substrate 10 and the circuit substrate 20. In some embodiments, the underfill resin layer 35 prevents the ball pad 11, the terminal pad 21 and the conductive ball 15 from eroding due to external humidity.

The modulus of elasticity of the underfill resin layer 35 may be lower than that of any of the first and second soldering fluxes 13 and 23. Thus, if at least one of the device substrate 10 and the circuit substrate 20 is deformed due to temperature variations, the underfill resin layer 35 can absorb the deformation. Accordingly, the underfill resin layer 35 is not released from the device substrate 10 and the circuit substrate 20 and the ball pad 11, the terminal pad 21 and the conductive ball 15 can be protected from external humidity, etc. Also, the first and second soldering fluxes 13 and 23 have a higher modulus of elasticity than that of the underfill resin layer 35, so that cracks occurring in the solder joint between the conductive ball 15 and the ball pad 11 and/or the terminal pad 21 can be prevented even when the device substrate 10 and/or the circuit substrate 20 are deformed due to temperature variations. In these embodiments, the first and second soldering fluxes 13 and 23 may be composed of the epoxy-based flux having a relatively high modulus of elasticity. It will be appreciated, however, that the first and second soldering fluxes 13 and 23 may be composed of any suitable material having a relatively high modulus of elasticity other than the aforementioned epoxy-based flux.

The modulus of elasticity of the underfill resin layer 35 at room temperature may range from about 1 GPa to 5 GPa. In some embodiments, the modulus of elasticity of the underfill resin layer 35 at room temperature may be about 4 GPa or less. Additionally, the glass transition temperature T_{g} of the underfill resin layer 35 may be lower than the maximum temperature of a temperature range of a thermal shock test performed to test the resultant mounting structure or semiconductor device. For example, when the thermal shock test is performed in the temperature range of 0° C.-125° C., the glass transition temperature T_{g} of the underfill resin layer 35 may be less than the maximum temperature of the temperature range of the thermal shock test of 125° C. Therefore, the underfill resin layer 35 may have a sufficient elasticity within the temperature range of the thermal shock test to absorb the deformation of at least one of the device substrate 10 and the circuit substrate 20.

In some embodiments, the underfill resin layer 35 may comprise a material such as polyimide resin, polyurethane resin, silicon resin, or the like or combinations thereof.

The underfill resin layer 35 may be formed by filling underfill resin between the device substrate 10 and the circuit substrate 20 using a capillary, after the device substrate 10 is connected to the circuit substrate 20 via the conductive ball 15. However, the method of forming the underfill resin layer 35 is not limited thereto and may be performed by forming the underfill resin layer 35 on the device substrate 10 having the conductive ball 15, disposing the device substrate 10 having the underfill resin layer 35 and the conductive ball 15 on the circuit substrate 20, and connecting the conductive ball 15 onto the circuit substrate 20.

Meanwhile, the naming of the mounting structure of the semiconductor device differs according to the kind of the device substrate 10 and the circuit substrate 20. More specifically, when the device substrate 10 is a semiconductor chip, the mounting structure of the semiconductor device may be referred to as a flip chip package. If the device substrate 10 is a circuit board mounted with another semiconductor chip, the mounting structure of the semiconductor device may be referred to as a BGA package. Also, when the device substrate 10 is a circuit board mounted with a semiconductor chip, and the circuit substrate 20 is a circuit board mounted with another semiconductor chip, the mounting structure of the semiconductor device may be referred to as a package on package (POP).

According to the embodiments exemplarily described above, a conductive ball may be connected to a ball pad using epoxy-based flux so that crack generation can be prevented from occurring in a solder joint between the conductive ball and the ball pad even when the device substrate is thermally deformed due to temperature variations. Furthermore, the conductive ball may be connected to a terminal pad using the epoxy-based resin flux, thereby preventing crack generation in the solder joint between the conductive ball and the terminal pad even when the circuit substrate is deformed due to temperature variations. Further, an underfill resin layer having a modulus of elasticity less than that of the flux may be provided so as to absorb any deformation that may be generated when the at least one of a device substrate and the circuit substrate is deformed due to temperature variations. Therefore, the underfill resin layer can be prevented from being released from at least one of the device substrate and the circuit substrate to thereby protect the ball pad, the terminal pad and the conductive ball from external humidity, etc.

While the embodiments of the present invention have been particularly shown and described, it will be understood by those of ordinary skill in the art that various changes in form and details may be made therein without departing from the spirit and scope of the present invention as defined by the following claims.

What is claimed is:

1. A semiconductor device, comprising:
a first substrate having a first pad;
a second substrate located over the first substrate, the second substrate having a second pad facing the first pad;
a conductive ball connecting the first pad to the second pad;
a first soldering flux located on a portion of the conductive ball adjacent to the second pad, the first soldering flux comprising an epoxy-based resin; and
an underfill layer between the first substrate and the second substrate, the underfill layer substantially surrounding the conductive ball and the first soldering flux.

2. The semiconductor device of claim 1, further comprising a second soldering flux connecting the conductive ball to the first pad, wherein the second soldering flux comprises an epoxy-based resin.

3. The semiconductor device of claim 1, wherein the first soldering flux comprises a filler.

4. The semiconductor device of claim 1, wherein a glass transition temperature of the first soldering flux is higher than a maximum temperature of a temperature range of a thermal shock test of the semiconductor device.

5. The semiconductor device of claim 1, wherein a modulus of elasticity of the underfill layer is less than a modulus of elasticity of the first soldering flux.

6. The semiconductor device of claim 5, wherein the underfill layer comprises a resin having a glass transition temperature lower than a maximum temperature of a temperature range of a thermal shock test of the semiconductor device.

7. The semiconductor device of claim 1, wherein the second substrate is a semiconductor chip or a circuit board mounted on a semiconductor chip.

8. The semiconductor device of claim 1, wherein the first soldering flux connects the conductive ball to the second pad.

9. A semiconductor device, comprising:
a circuit substrate having a terminal pad;
a device substrate located over the circuit substrate, the device substrate having a ball pad facing the terminal pad;
a conductive ball connecting the terminal pad to the ball pad;
a first soldering flux located on a portion of the conductive ball adjacent to the ball pad; and
an underfill layer between the circuit substrate and the device substrate, the underfill layer substantially surrounding the conductive ball and the first soldering flux, wherein a modulus of elasticity of the underfill layer is less than a modulus of elasticity of the first soldering flux.

10. The semiconductor device of claim 9, further comprising a second soldering flux connecting the conductive ball to the terminal pad.

11. The semiconductor device of claim 9, wherein the first soldering flux connects the conductive ball to the ball pad.

12. A method of forming a semiconductor device, the method comprising:
providing a first substrate having a first pad;
forming a conductive ball on the first pad using a first soldering flux comprising an epoxy-based resin;
disposing the first substrate on a second substrate having a second pad;
connecting the conductive ball to the second pad; and
forming an underfill layer between the second substrate and the first substrate to substantially surround the conductive ball and the first soldering flux.

13. The method of claim 12, which further comprises connecting the conductive ball to the second pad using a second soldering flux comprising an epoxy-based resin.

14. The method of claim 12, wherein the first soldering flux comprises a filler.

15. The method of claim 12, which further comprises subjecting the semiconductor device to a thermal shock test, wherein a glass transition temperature of the first soldering flux is higher than a maximum temperature of a temperature range of the thermal shock test.

16. The method of claim 12, wherein a modulus of elasticity of the underfill layer is less than a modulus of elasticity of the first soldering flux.

17. The method of claim 16, which further comprises subjecting the semiconductor device to a thermal shock test, wherein the underfill layer comprises a resin having a glass transition temperature lower than a maximum temperature of a temperature range of the thermal shock test.

18. The method of claim 12, wherein the first substrate is a semiconductor chip or a circuit board mounted with a semiconductor chip.

19. The method of claim 12, which further comprises connecting the conductive ball to the first pad using the first soldering flux.

20. A method of forming a semiconductor device, the method comprising:
providing a device substrate having a ball pad;
connecting a conductive ball on the ball pad using a first soldering flux;
disposing the device substrate on a circuit substrate having a terminal pad;
connecting the conductive ball to the terminal pad; and
forming an underfill layer between the circuit substrate and the device substrate to substantially surround the conductive ball and the first soldering flux, wherein a modulus of elasticity of the underfill layer is less than a modulus of elasticity of the first soldering flux.

21. The method of claim 20, which further comprises connecting the conductive ball to the terminal pad using a second soldering flux.
